(19) United States
(12) Patent Application Publication
(10) Pub. No.: US 2004/0047137 A1
(43) Pub. Date: Mar. 11, 2004

(54) Module mounting system

(76) Inventors: Jose Quero, Freiberg (DE); Achim Stirner, Huttlingen (DE); Vassilios Tsirogiannis, Kirchheim/N (DE)

Correspondence Address: FISH & RICHARDSON PC, 225 FRANKLIN ST, BOSTON, MA, 02110, US

(21) Appl. No.: 10/429,239

(22) Filed: May 5, 2003

(30) Foreign Application Priority Data
May 3, 2002 (EP) 02009908

(51) Int. Cl. H05K 7/02; H05K 7/04

(52) U.S. Cl. 361/807

(57) ABSTRACT

A mounting system, in particular for a switch cabinet, comprises a rapid mounting plate and several modules each of which comprises a functional construction unit for transferring an electric function for control and regulation of a processing unit or a machine or a plant and a module carrier for the functional construction unit. The modules are detachable mounted to the rapid mounted plate. Each module has an interface for a bus system (energy and data bus) for electric connection between the modules.

### PRIORITY STATEMENT

This application claims priority to European application, BP 02009908, filed on May 3, 2002, which is incorporated herein by reference in its entirety.

### FIELD OF THE INVENTION

This invention concerns mounting of modules, in particular, for a switch cabinet.

### BACKGROUND

Mounting systems in a switch cabinet are disclosed, e.g., in German patent DE 197 43 974 A1, which describes a switch cabinet comprising a switch cabinet box with several modules. The modules are disposed onto a bearing rail that is disposed in the switch cabinet and has the shape of a hat and serves as module carrier. The individual modules are connected by contact tongues in the modules.

### SUMMARY

It is an underlying purpose of the invention to further improve mounting of modules, in particular in a switch cabinet.

This object is achieved by a rapid mounting system wherein the modules (i.e., a module carrier with components and a bus) are detachable mounted to a rapid mounting plate, e.g., a cabinet wall of a switch cabinet housing, wherein each module comprises an interface for a bus system (energy and data bus) for electrical connection between the modules. The rapid mounting plate may be part of a switch cabinet housing or machine housing or be mounted there or at another location.

The components can be (neutrally) pre-mounted on the module carrier independent of the machines and component such that they can be used in the manner of a construction kit system. The mounted modules are connected by a multipolar bus cable that is suited for transmitting energy and data.

The above-mentioned object is also achieved by a method for projecting modules, characterized by parameterization of a processing unit of a machine or plant, a selection of pre-fabricated modules from a database, production of a layout of a rapid mounting plate, preferably a switch cabinet wall, and optional arrangement and connection of the selected modules to the rapid mounting plate. Within the framework of the invention, the method steps can be carried out sequentially in any order or also in parallel. A processing unit means, e.g., a sorting, charging or discharging, separating, cutting unit etc.

The invention facilitates automatic module production, further reduces the mounting hours for switch cabinet construction, reduces the construction time for new projects, reduces the processing times of the switch cabinet, permits free selection of variants for final mounting, options without unnecessary parts, provides simple and secure mounting of structural parts and construction units (easy maintenance), centralized and decentralized construction with the same modules and simple adjustment to different machine constellations.

Detachable mounting can be realized through insertion or hanging the module carrier by means of rapid attaching means to the rapid mounting plate, e.g., the cabinet wall of the switch cabinet.

In another embodiment, which is easy to realize and simple to handle, the module carrier for a module is formed by a module carrier plate comprising shackles, wherein the rapid mounting plate comprises recesses into which the shackles can be inserted or hung.

For module control and coordination of cooperation of several modules, the modules have an interface and/or a network board for coupling to a control unit of a machine.

In a first general aspect, a mounting system includes a rapid mounting plate, a plurality of functional construction units connected to module carriers and detachable mounted on the mounting plate for transferring an electrical function for control and regulation of a processing unit of a machine or plant, and a plurality of module carriers housing the functional construction units. Each functional construction unit has an interface for a bus system for electrical connection between the functional control units.

This aspect may include one or more of the following features. For example, the rapid mounting plate may be adapted for connection to a switch cabinet. The module carriers may be adapted to be plugged into recesses in the rapid mounting plate. The module carriers may be adapted for hanging into recesses of the rapid mounting plate. The module carriers may include module carrier plates having shackles which can be inserted into the recesses. The module carrier plates may include shackles which can be inserted into the recesses. At least one functional construction unit may include an interface and/or a network board for coupling to a control unit of the machine. At least one functional construction unit may include an interface and/or a network board for coupling to a control unit of the machine. At least one functional construction unit may include an interface and/or a network board for coupling to a control unit of the machine. At least one functional construction unit may include an interface and/or a network board for coupling to a control unit of the machine. At least one functional construction unit may include an interface and/or a network board for coupling to a control unit of the machine. At least one functional construction unit may include an interface and/or a network board for coupling to a control unit of the machine.

In a second general aspect, a method of projecting modules to a rapid mounting plate of a mounting system includes parameterizing a processing unit of a machine or a plant, selecting representations of pre-fabricated modules from a database, and producing a layout of a rapid mounting plate based on the selected representations of pre-fabricated modules.

This aspect may include one or more of the following features. For example, the method may also include physically positioning modules on a rapid mounting plate in an arrangement based on the layout, and electrically connecting the physical modules. Physically positioning the modules on the rapid mounting plate may include physically positioning the modules within a switch cabinet.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 is a schematic diagram showing the principle of the modular arrangement of a functional construction unit of a module carrier for mounting in a switch cabinet

FIG. 2 is a perspective view of a module carrier mounting mounted to a cabinet wall of the switch cabinet.

FIG. 3 is a perspective view of a cabinet wall of a switch cabinet with several functional construction units.

FIG. 4 is a schematic view of energy and data lines for a module.

FIG. 5 is a schematic view of a second arrangement of energy and data lines of a module.

FIG. 6 is a schematic representation of the selection of modules for a switch cabinet for a switch cabinet.

FIG. 7 is a schematic view of the transfer of the arrangement and connection of the selected modules according to FIG. 6 to a layout of the switch cabinet wall.

Like reference symbols in the various drawings indicate like elements.

### DETAILED DESCRIPTION

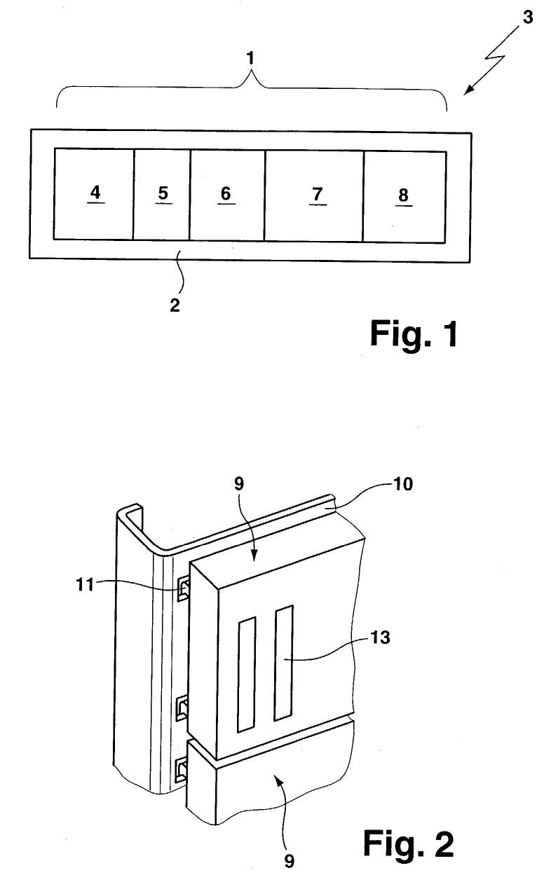

FIG. 1 shows schematically the structural components for control and regulation of an energy supply/current supply of an electricity consumer, e.g., a motor, an RF generator, a valve or a heating element, disposed as functional construction unit 1 on a module carrier 2, e.g., made of sheet metal. Analogous to this functional construction unit 1, which is exemplarily described, any number of further functional construction units may be premounted. The functional construction unit 1 and module carrier 2 are part of a module and construction kit system irrespective of the machine and structural components that can comprise a plurality of these multifunctional components. The produced neutral modules 3 are oriented in accordance with the functional construction units. The modules 3 of the functional construction unit 1 and the module carrier 2, can be plugged, detected, controlled and combined with other components on the switch cabinet in the manner of “plug & play.”

The functional construction unit 1 comprises the following components, which are only schematically indicated in the drawing: a network board 4, a protective switch 5, a switch 6, a terminal 7, and a bus interface 8. It would also be feasible to provide another functional construction unit that can serve for control of a servo drive, a right-left-drive, a voltage supply, a bus switch (gateway), etc. The most different structural components and function can be combined into one functional construction unit.

The following cooperating functions are realized in detail by the structural components. The network board 4 serves as a software and hardware interface for coupling the functional construction unit 1 to a central control of the electricity consumer. The protective switch 5, prevents overload of the module or of the electricity consumer. The electricity consumer can be switched on or off by means of the switch or contactor 6. The electricity consumer is connected to an energy supply/current supply by a terminal 7 realized through plug contacts. The connection of the functional construction unit 1 to one or more functional construction units is realized by the bus interface 8.

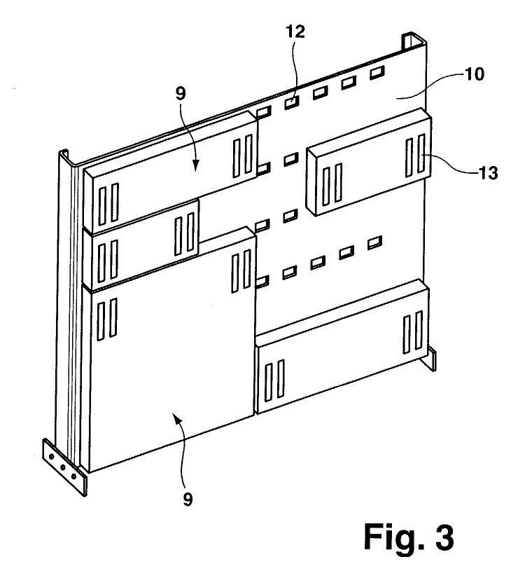

FIG. 2 shows how the modules 9 oriented in functional construction units can be hung each by module carriers to a rapid mounting plate, formed by a cabinet wall 10 produced from sheet metal, of a known switch cabinet housing (not shown) by shackles 11, which are inserted in recesses 12 (FIG. 3). Coupling of the functional construction units of the modules 9 is achieved by interfaces 13 (only indicated) without showing the connecting cable to the bus system. The cabinet wall 10 has a plurality of such recesses 12 to place the module carrier in different positions and/or provide further module carriers with further functional units. The module carrier that is mounted in an exchangeable and detachable fashion, can be additionally attached on the cabinet wall 9 by a mounting screw or a latch.

FIG. 3 shows the partial occupation of the cabinet wall 10 of the switch cabinet housing with several modules 9 of different functional construction units.

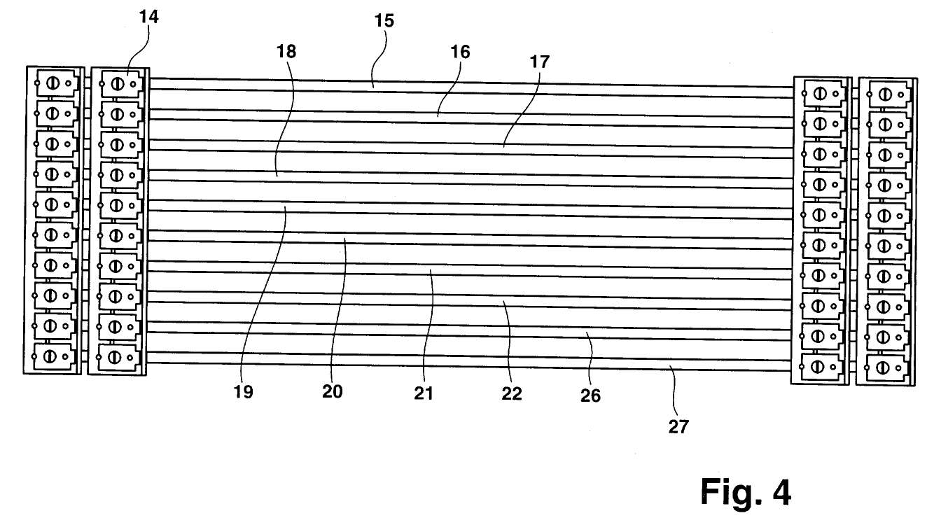

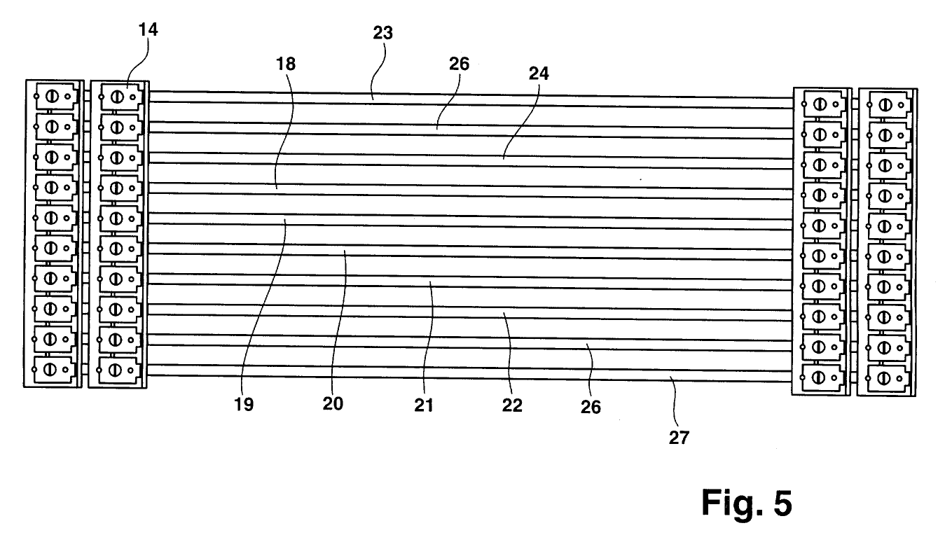

Each module has interfaces for coupling to a central control unit or to further modules. Two rows of plug contacts 14 each are provided on each side. FIG. 4 shows three energy transmission lines 15 through 17 and a protective conductor 18 for rotary current to drive, e.g., a motor. Lines 19 (24 V DC) and 20 (0 V DC) permanently supply energy to an electricity consumer, such as a light or a valve, while 24 V DC or 0 V DC are present at the lines 21 and 22 only with corresponding circuit. In contrast to the embodiment shown in FIG. 4, FIG. 5 concerns an embodiment for alternating current with a line 23 for 230 V AC and an alternative line 24 for 115 V AC and a common zero conductor 25. Each embodiment has additional data lines 26 and 27.

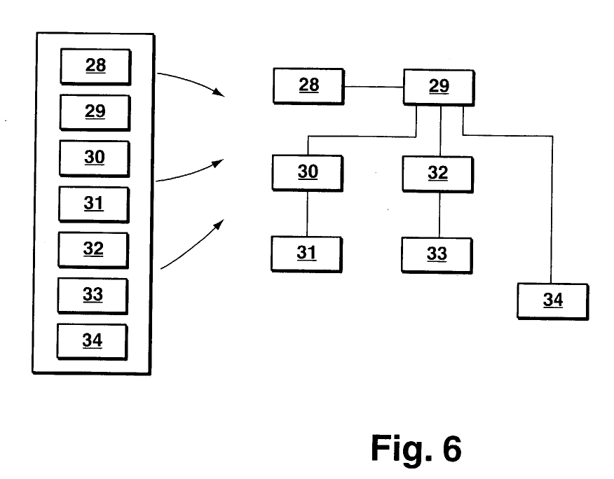

For construction of a switch cabinet for a plant or machine, the required parameters or data are detected an/or predetermined for operating the plant or machine. Then, prefabricated modules 28 through 34, which are stored in a database of many pre-fabricated modules and realize one certain function each, are selected as indicated in FIG. 6. The construction of the switch cabinet comprises parameterization, i.e., predetermination and introduction of data of the required function for operation of the plant or machine and on the other hand selection and arrangement/positioning of the modules 28 through 34 in the switch cabinet. After combination of the modules 28 through 34, described in detail above, in accordance with parameterization, the modules 28 through 34 are positioned and electrically connected by the energy and data bus (FIG. 4 and 5).

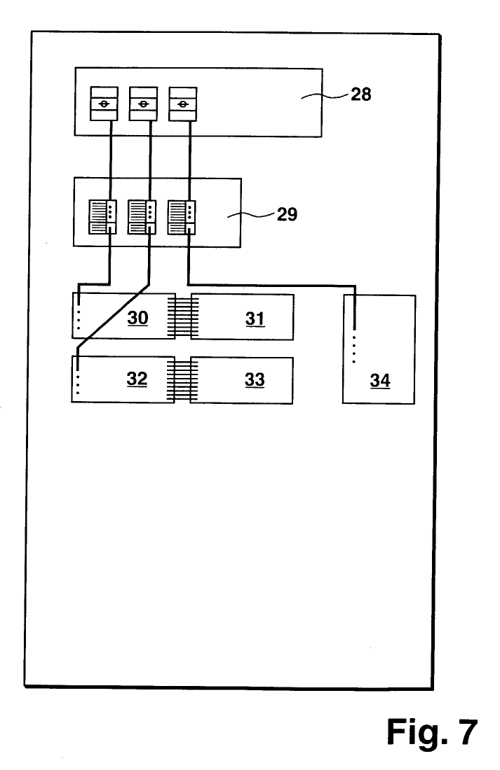

The principal design of and connection of the modules 28 through 34 is then transferred into a more concrete physical layout of a switch cabinet wall. FIG. 7 shows the layout of the physical components of a switch cabinet wall as coordinated with the principal logic according to FIG. 6 in a designed switch cabinet wall on which the modules 28 through 23 are disposed and connected.

### OTHER EMBODIMENTS

A number of embodiments of the invention have been described. Nevertheless, it will be understood that various modifications may be made. Accordingly, other embodiments are within the scope of the following claims.

What is claimed is:

1. A mounting system comprising:
a rapid mounting plate,
a plurality of functional construction units connected to module carriers and detachable mounted on the mounting plate for transferring an electrical function for control and regulation of a processing unit of a machine or plant; and
a plurality of module carriers housing the functional construction units,
wherein each functional construction unit has an interface for a bus system for electrical connection between the functional control units.

2. The mounting system of claim 1, wherein the rapid mounting plate is adapted for connection to a switch cabinet.

3. A mounting system according to claim 1, wherein the module carriers are adapted to be plugged into recesses in the rapid mounting plate.

4. A mounting system according to claim 1, wherein the module carriers are adapted for hanging into recesses of the rapid mounting plate.

5. The mounting system of claim 3, wherein the module carriers comprise module carrier plates having shackles which can be inserted into the recesses.

6. The mounting system of claim 4, wherein the module carrier plates comprise shackles which can be inserted into the recesses.

7. The mounting system according to claim 1, wherein at least one functional construction unit comprises an interface and/or a network board for coupling to a control unit of the machine.

8. The mounting system according to claim 2, wherein at least one functional construction unit comprises an interface and/or a network board for coupling to a control unit of the machine.

9. The mounting system according to claim 3, wherein at least one functional construction unit comprises an interface and/or a network board for coupling to a control unit of the machine.

10. The mounting system according to claim 4, wherein at least one functional construction unit comprises an interface and/or a network board for coupling to a control unit of the machine.

11. The mounting system according to claim 5, wherein at least one functional construction unit comprises an interface and/or a network board for coupling to a control unit of the machine.

12. The mounting system according to claim 6, wherein at least one functional construction unit comprises an interface and/or a network board for coupling to a control unit of the machine.

13. A method of projecting modules to a rapid mounting plate of a mounting system comprising:
parameterizing a processing unit of a machine or a plant;
selecting representations of pre-fabricated modules from a database; and
producing a layout of a rapid mounting plate based on the selected representations of pre-fabricated modules.

14. The method of claim 13, further comprising:
physically positioning modules on a rapid mounting plate in an arrangement based on the layout; and
electrically connecting the physical modules.

15. The method of claim 13, wherein physically positioning the modules on the rapid mounting plate comprises physically positioning the modules within a switch cabinet.
